(19) United States
(12) Patent Application Publication
(10) Pub. No.: US 2025/0186999 A1
(43) Pub. Date: Jun. 12, 2025

(54) FLUIDIC SYSTEM AND METHOD FOR OPERATING A FLUIDIC SYSTEM

(71) Applicant: HNP MIKROSYSTEME GMBH, Schwerin (DE)

(72) Inventors: Tim POLLEY, Schwerin (DE); André HARMEL, Schwerin (DE); Gerald VOEGELE, Sindelfingen (DE); Thomas WEISENER, Schwerin (DE)

(73) Assignee: HNP MIKROSYSTEME GMBH, Schwerin (DE)

(21) Appl. No.: 18/843,807

(22) PCT Filed: Mar. 8, 2023
(86) PCT No.: PCT/EP2023/055899

§ 371 Date: Sep. 4, 2024

(30) Foreign Application Priority Data
Mar. 9, 2022 (DE) 10 2022 105 467.5
May 6, 2022 (DE) 10 2022 111 381.7

(51) Int. Cl. B01L 3/00

(52) U.S. Cl. CPC B01L 3/502715; B01L 3/50273; B01L 2300/044; B01L 2300/0816; B01L 2400/043; B01L 2400/0481

(57) ABSTRACT

The invention relates to a fluidic system with a fluidic element and a transport device. The fluidic element comprises a basic body and a deformable membrane, the basic body comprising at least one first channel and at least one second channel for guiding a fluid, with at least one outlet being formed at one end of the first channel and at least one inlet being formed at one end of the second channel, and the membrane being connected to the basic body and covering at least the outlet of the first channel and the inlet of the second channel. The transport device comprises an actuator, the actuator being designed to deform the membrane such that a cavity is formed between the basic body and the membrane. The actuator comprises a magnetic shape memory alloy or consists thereof.

### TECHNICAL FIELD

The invention relates to a fluidic system and a method for operating a fluidic system.

### TECHNICAL BACKGROUND

Fluidic elements or microfluidic elements, such as lab-on-a-chip (LoC) elements, are increasingly being used to transport, treat or analyze samples. One area of application is point-of-care diagnostics (PoC). The fluidic elements may include a process unit in which the sample is subjected to a chemical, physical or biological process. The fluidic elements or microfluidic elements may be used in insulin pumps or infusion pumps.

As a rule, a very small volume of fluid or a very small flow rate (volume flow), possibly together with the sample and/or an active ingredient, is passed through the fluidic element. The precise dosing of very small volumes of fluid is demanding, but important for LoC elements, for example. Inaccuracies in the volume flow passed through the fluidic element may, for example, cause inaccuracies in the residence time of a sample in the LoC element, which may negatively affect an analysis.

The fluidic elements may be configured for single use, i.e. after the fluidic element has been used once, the fluidic element may be disposed of. The fluidic elements may be configured as disposable items. For this purpose, the fluidic elements are manufactured inexpensively in large quantities.

The transport device providing a volume flow through the fluidic element is considerably more expensive than the fluidic element.

WO 2019 008 235 A1 shows a microfluidic device comprising at least one element made of magnetic shape memory material (MSM) for handling a fluid flow, wherein the MSM element is controlled by a magnetic field. The device comprises elastic material between the fluid being handled and the MSM element, and the magnetic field is arranged such that it causes local shrinkage of the MSM element, which together with the elastic material forms a shrinkage cavity at a location where the magnetic field is applied to the MSM element. The microfluidic device may be connected to a lab-on-a-chip.

### SUMMARY OF THE INVENTION

It is an object of the invention to provide a fluidic element that can be easily connected to a transport device for single use. Another object of the invention is to provide a fluidic system or a fluidic element that can be operated so as to be reliable in process and is inexpensive to manufacture. Yet another object of the invention is to provide a fluidic system or a fluidic element through which a volume flow can be passed with relatively high accuracy and in which an actuator does not come into direct contact with the fluid passed through the fluidic element. Yet another object of the invention is to provide a fluidic system or a fluidic element through which a volume flow can be passed relatively constantly.

Another object of the invention is to provide a fluidic system, the fluidic element of which can be easily connected to a transport device for single use.

At least one of the objects is achieved by the combination of features of the independent claims.

A fluidic element is disclosed. The fluidic element comprises a basic body with at least one first channel and at least one second channel for guiding a fluid. At least one outlet is formed at one end of the first channel. At least one inlet is formed at one end of the second channel. The fluidic element comprises a deformable membrane. The deformable membrane is connected to the basic body. The deformable membrane covers at least the outlet of the first channel and the inlet of the second channel. The membrane can be deformed by an actuator in the direction of the actuator such that a movable cavity is formed between the basic body and the membrane in order to transport the fluid from the outlet of the first channel to the inlet of the second channel.

The fluidic element may be a microfluidic element. In particular, the fluidic element is a lab-on-a-chip element. The fluidic element or the microfluidic element may be used in an insulin pump unit or in an infusion pump unit.

The basic body of the fluidic element may comprise a plastic or consist of plastic. The basic body of the fluidic element may comprise a metal or consist of metal. Likewise, the basic body of the fluidic element may comprise a ceramic material or consist of a ceramic material.

The basic body is preferably produced by injection molding. The basic body may be an injection molded part.

At least a first channel and a second channel may be formed in the basic body. In addition to the first channel and the second channel, further channels may be formed in the basic body. Each of the channels may be formed completely in the basic body. In particular, all sides of the channels are surrounded by the material of the basic body, with an inlet and an outlet being formed respectively.

The channels may be embossed, milled or etched into the basic body.

The channels may have a cross-sectional area (perpendicular to the flow direction through the respective channel) of at most 2500 mm², preferably at most 2000 mm², more preferably at most 1500 mm², more preferably at most 1000 mm², more preferably at most 500 mm², more preferably at most 300 mm², more preferably at most 100 mm², more preferably at most 50 mm², more preferably at most 30 mm², more preferably at most 1.0 mm², more preferably at most 0.1 mm², more preferably at most 0.01 mm², more preferably at most 0.001 mm². The channels particularly preferably have a cross-sectional area between 20 mm² and 0.0004 mm².

Each of the channels may be configured to carry a fluid.

In general, a fluid may be a gas or a liquid. The fluid may also be a mixture of a gas and a liquid. The fluid may contain a solid. The majority of the fluid (more than 50% by volume) may be liquid and/or gaseous.

The fluid may comprise a sample and/or an active ingredient. The sample and/or the active ingredient may be a solid, a liquid and/or a gas. The sample may be a substance to be treated or analyzed or a mixture of substances. As part of the treatment or analysis, the substance or mixture of substances may be subjected to at least one chemical, physical and/or biological process. The active ingredient may be a substance that is supplied to a living being (human or animal). The active ingredient may be used to treat the living being. For example, the active ingredient is insulin.

Each of the channels may have an inlet and an outlet. A fluid may be introduced into the channel at the inlet. The fluid may be discharged from the channel at the outlet. The flow direction may be defined to be from the inlet towards the outlet. Alternatively, the flow direction may be defined to be from the outlet towards the inlet. In other words, the flow direction may be reversible.

The membrane may be deformable, flexible and/or elastic. The membrane may have a thickness that is several times smaller than its width and/or length. The thickness of the membrane may be a maximum of 2.0 mm, preferably a maximum of 1.0 mm, more preferably a maximum of 0.7 mm, more preferably a maximum of 0.5 mm, more preferably a maximum of 0.3 mm, more preferably a maximum of 0.2 mm, more preferably a maximum of 0.1 mm, more preferably a maximum of 0.01 mm. The thickness of the membrane is particularly preferably between 0.005 mm and 0.200 mm.

The membrane may have an area (perpendicular to the thickness of the membrane) of at least 1 mm², preferably at least 10 mm², more preferably at least 50 mm², more preferably at least 100 mm², more preferably at least 300 mm², more preferably at least 500 mm², more preferably at least 1000 mm², more preferably at least 1500 mm², more preferably at least 2500 mm², more preferably at least 5000 mm², more preferably at least 10000 mm².

The membrane may have an area of at most 10000 mm², more preferably at most 1000 mm², more preferably at most 200 mm².

The area of the membrane is particularly preferably between 5 mm² and 200 mm².

The membrane may be formed to be single-layered or multi-layered. The membrane may comprise a plastic or consist of plastic. The plastic may be a thermoplastic or an elastomer, in particular a thermoplastic elastomer. The membrane may comprise a metal or consist of metal. The membrane may comprise a composite material or consist of a composite material.

The membrane is connected to the basic body. The connection between the membrane and the basic body may be firm. In particular, the connection between the membrane and the basic body may be configured such that the membrane cannot be removed from the basic body (without aids) without causing damage or destruction. Alternatively, the connection between the membrane and the basic body may be configured such that the membrane can be removed from the basic body without causing damage or destruction, in particular without aids.

In particular, the membrane is glued or welded to the basic body. For example, the membrane may be welded to the basic body using ultrasound or laser.

The membrane covers at least the outlet of the first channel and the inlet of the second channel. The membrane may completely overlap or cover at least the outlet of the first channel and the inlet of the second channel.

At least one side of the basic body may have a flat or planar portion. The outlet of the first channel and the inlet of the second channel may be formed in the portion or open into the portion. The membrane may be connected to the basic body in the portion. In particular, the area of the flat or planar portion is larger than the area of the membrane.

The membrane may be deformed by an actuator towards the actuator. In particular, the membrane may be deformed away from the basic body. In other words, the membrane may be deformed by the actuator such that a portion of the membrane is lifted or raised from the basic body.

A cavity may be formed between the basic body and the membrane by the deformation. The cavity may extend in towards the actuator. The cavity may extend away from the basic body.

The cavity may be formed at least temporarily in the region of the outlet of the first channel so that a fluid can flow from the outlet of the first channel into the cavity.

The cavity can be moved by the actuator, in particular toward the inlet of the second channel. In particular, the cavity can be moved so that the cavity is not in fluidic communication with the outlet of the first channel and with the inlet of the second channel. When the cavity is not in fluidic communication with the outlet of the first channel and the inlet of the second channel, the fluid in the cavity may be (completely) separated or isolated from the environment. In other words, the cavity may be (completely) surrounded or enclosed by the basic body and the membrane. By further moving the cavity towards the inlet of the second channel, the cavity with the fluid may come into fluidic communication with the inlet of the second channel. The fluid may flow or be introduced from the cavity into the second channel via the inlet of the second channel. This allows for a fluid to be transported from the first channel into the second channel.

The membrane may be connected to a surface of the basic body via an attachment. The attachment may completely surround a surface portion of the membrane.

The attachment may completely surround a surface portion of the basic body. The outlet of the first channel and the inlet of the second channel may be formed in or open into the surface portion of the basic body that is completely surrounded by the attachment.

The attachment may be an adhesive seam or a weld seam.

A sample can possibly be introduced into the fluidic element. The fluidic element may comprise a process unit. The sample may be treatable by a chemical, physical and/or biological process in the process unit. In particular, the sample in the process unit may be analyzable by or with the aid of a chemical, physical and/or biological process. The process unit may comprise an assay, for example a biochemical assay or an immunoassay. The process unit may also comprise a chromatographic element. In general, the process unit may comprise one or more sensors.

The membrane may be connected to the basic body in such a way that a portion of the membrane that is not deformed by the actuator contacts the basic body.

When the membrane is not deformed by the actuator, the membrane may at least partially, in particular completely, rest against the basic body or contact it.

A fluidic system is disclosed. The fluidic system comprises a fluidic element and a transport device. The fluidic element comprises a basic body and a deformable membrane. The basic body has at least one first channel and at least one second channel for guiding a fluid or has at least the first channel and at least the second channel. At least one outlet is formed at one end of the first channel. At least one inlet is formed at one end of the second channel. The membrane is connected to the basic body. The membrane covers at least the outlet of the first channel and the inlet of the second channel. The transport device comprises an actuator. The actuator is configured to deform the membrane such that a cavity is formed between the basic body and the membrane.

The fluidic system may comprise any fluidic element disclosed herein. The fluidic system may be a microfluidic system.

The transport device may be a pumping device for transporting a liquid. In particular, the transport device is a micropump device. A micropump device may have a maximum delivery rate of a maximum of 100 ml per minute, preferably a maximum of 10 ml per minute, more preferably a maximum of 5 ml per minute, more preferably a maximum of 1 ml per minute.

The actuator may comprise a magnetic shape memory alloy (MSMA) or consist of a magnetic shape memory alloy.

A shape of a magnetic shape memory alloy may be changed by applying a magnetic field. Here, twin boundaries in magnetic shape memory alloys are movable by a magnetic field, resulting in a magnetically induced reorientation of the material. The material may be stretched by a vertical magnetic field and the material may be contracted by a parallel magnetic field. The basic principle of a magnetic field-induced change in shape of an actuator made of a material with a twin boundary is described in U.S. Pat. No. 6,515,382 B1, to which reference is made.

The magnetic shape memory alloy may be a nickel-manganese-gallium alloy. The actuator may be a pumping actuator.

The actuator may be substantially cuboid-shaped.

The transport device may comprise a drive. The drive may be configured to deform the actuator. In particular, the drive is configured to generate a magnetic field.

The drive may be able to generate a homogeneously directed traveling magnetic field. For this purpose, the drive comprises in particular electromagnetic coils and/or permanent magnets. In particular, the drive may generate and move a plurality of traveling magnetic fields at the same time.

The drive may be able to generate a rotating magnetic field. For this purpose, the drive may comprise a magnet, in particular a diametrically magnetized magnet. The magnet may be rotatable. In particular, the drive is configured to rotate the magnet. The rotation may be carried out around a central axis of the magnet.

In general, the magnetic field may be oriented (at different times) perpendicular or parallel to the longitudinal extension of the actuator.

The transport device may comprise at least one sensor.

The transport device may comprise a temperature sensor that measures the temperature of the actuator. A control unit may change the operation of the transport device based on the value detected by the temperature sensor. In particular, the control unit may change the operation of the transport device when the temperature value of the actuator detected by the temperature sensor exceeds and/or falls below a specified temperature threshold.

The transport device may comprise at least one pressure sensor that detects the pressure at the outlet of the first channel and/or at the inlet of the second channel. Based on the value detected by the at least one pressure sensor, the operation of the transport device may be changed (e.g. by a control unit).

The actuator and the membrane may be coupled to one another in such a way that a deformation of the actuator causes a deformation of the membrane. In particular, the actuator and the membrane may be coupled to one another in such a way that a deformation of the actuator causes a corresponding deformation of the membrane.

The actuator may be deformed by the drive of the transport device, in particular by generating a magnetic field by the drive. The actuator may be coupled or connected to the membrane in such a way that the deformation of the actuator is transmitted or passed on to the membrane. As a result, a deformation of the membrane may be closed-loop or open-loop controlled by the drive.

The actuator may be connected to the membrane directly or indirectly. In particular, the actuator contacts the membrane directly or indirectly. In the case of indirect contact, another element may be present between the actuator and the membrane, for example an adhesive agent or an adhesion-promoting structure.

The actuator may have a greater length than a distance between the outlet of the first channel and an inlet of the second channel. The actuator may be arranged such that the actuator overlaps or covers the outlet of the first channel and the inlet of the second channel.

The actuator may be connected to the membrane by an adhesive force (adhesion force). The adhesive force may couple or connect the actuator and the membrane to one another in such a way that a deformation of the actuator causes or effects a (corresponding) deformation of the membrane.

The adhesive force may be provided by a liquid. The liquid may be present between the actuator and the membrane. The liquid is preferably silicone oil (e.g. diorganopolysiloxane). The liquid may have a higher viscosity than water. Likewise, the liquid may have a higher viscosity than the fluid that is to be or is being passed through the fluidic element.

In general, an adhesion film may be arranged between the actuator and the membrane. Both the actuator and the membrane may contact the adhesion film. An adhesion film may increase adhesion between the actuator and the membrane, in particular compared to the adhesion between the actuator and the membrane without the adhesion film.

The adhesive force may be provided by an adhesion medium that was provided by breaking open capsules between the actuator and the membrane.

For example, capsules may be arranged between the actuator and the membrane. The capsules may each comprise a shell that surrounds or encloses an adhesion medium. By pressing the actuator and the membrane together, the capsules may be broken open or damaged, releasing the adhesion medium. The adhesion medium may provide the adhesive force between the actuator and the membrane. The adhesion medium may be a liquid, in particular silicone oil. The liquid may have a higher viscosity than water. Likewise, the liquid may have a higher viscosity than the fluid that is to be passed or is being passed through the fluidic element.

The adhesive force may be provided by a gel. The gel may be arranged between the actuator and the membrane. In particular, the adhesive force may be provided by a hydrocolloid film.

For example, a hydrocolloid may be provided between the actuator and the membrane. The hydrocolloid may be a polysaccharide or a protein. The hydrocolloid may adhere to the actuator or the membrane before the actuator and the membrane are brought into contact.

By adding a liquid, for example water, the hydrocolloid may form a hydrocolloid film between the actuator and the membrane.

The actuator may be connected to the membrane by an adhesive bond. An adhesive, by means of which the actuator is connected to the membrane, may be arranged between the actuator and the membrane. The adhesive bond may be detachable. Alternatively, the bond may be configured such that the connection between the actuator and the membrane cannot be released (without aids) without causing damage or destruction. For example, the adhesive bond may be configured such that it is weakened by heating. The adhesive bond may be configured such that it can be released by heating. Without heating, the connection between the actuator and the membrane cannot be released without causing damage or destruction.

The adhesive bond may be provided by an adhesive film between the actuator and the membrane. The adhesive film can be understood to be an adhesive or adhesive agent. For example, an adhesive film in non-solidified form may be introduced between the actuator and the membrane. The adhesive film may solidify between the actuator and the membrane. This may provide the connection between the actuator and the membrane.

The adhesive film may be an elastic adhesive. This allows the actuator to be removed or released from the membrane without causing damage or destruction.

The adhesive bond may be provided by an adhesive membrane between the actuator and the membrane. An adhesive membrane may comprise a non-sticky carrier and an adhesive or an adhesive agent. The adhesive or the adhesive agent of the adhesive membrane may not be solidified or become solidified.

For example, the membrane may be provided with an adhesive or an adhesive agent on one side. The adhesive or the adhesive agent may not be solidified or become solidified. When the actuator is pressed against the membrane, the adhesive or the adhesive agent creates a connection between the actuator and the membrane. The actuator can be removed or detached from the membrane without causing any damage or destruction.

Similarly, a two-sided adhesive membrane may be provided between the actuator and the membrane. An adhesive or an adhesive agent may be provided on both (flat) sides of the adhesive membrane. The adhesive effect of the adhesive or the adhesive is preferably greater on one side of the adhesive membrane than on the other (opposite) side of the adhesive membrane. The two-sided adhesive membrane may be arranged between the actuator and the membrane and the actuator may be pressed onto the membrane. This allows for the actuator to be connected to the membrane. The actuator can be removed or detached from the membrane without causing any damage or destruction.

The actuator may be bonded to the membrane by van der Waals forces and/or electrostatic forces. In particular, the actuator and/or the membrane have a plurality of adhesive elements. Alternatively, a further membrane with a plurality of adhesive elements may be arranged between the actuator and the membrane. The further membrane may comprise a plurality of adhesive elements on both (flat) sides.

When the actuator and the membrane are brought into contact (possibly with an intermediate membrane), increased van der Waals forces and/or electrostatic forces may act between the actuator and the membrane (gecko effect). This allows the actuator to be connected to the membrane. The actuator can be removed or detached from the membrane without causing any damage or destruction.

The actuator may be connected to the membrane by negative pressure. A negative pressure may exist between the actuator and the membrane. The negative pressure may be lower than the ambient pressure, in particular lower than 1 bar. For this purpose, the fluidic element and/or the transport device may comprise a vacuum unit. The vacuum unit may also be provided outside the fluidic element and the transport device. The vacuum unit may generate a vacuum between the actuator and the membrane.

The connection between the actuator and the membrane is preferably pressure-tight. The pressure-tight connection can maintain a negative pressure between the actuator and the membrane.

The actuator may be connected to the membrane by a magnetic force. The membrane may be magnetic. In particular, the membrane is ferromagnetic. The actuator may be magnetic.

When the actuator and the membrane are brought into contact, a connection between the actuator and the membrane may be created by a magnetic force. The actuator can be removed or detached from the membrane without causing any damage or destruction.

In particular, the membrane is multi-layered or multi-ply. The membrane may comprise at least one magnetic, preferably at least one ferromagnetic, layer or ply. For example, the magnetic layer or ply may be located closer to the side of the membrane that is or comes into contact with the actuator than to the side of the membrane that is or comes into contact with the fluid. The side of the membrane that is or comes into contact with the fluid may not include or be a magnetic layer or ply. In particular, the side of the membrane that is or comes into contact with the fluid is resistant to the fluid.

A method for operating a fluidic system is disclosed. The method comprises the steps of: deforming a membrane connected to a basic body by means of an actuator towards the actuator so that a cavity is formed between the basic body and the membrane; introducing a fluid from an outlet of a first channel of the basic body into the cavity; moving the cavity with the fluid by means of the actuator towards an inlet of a second channel; introducing the fluid into the second channel via the inlet.

The fluidic system may be any fluidic system disclosed herein. Any fluidic element disclosed herein may be used in the method. Any transport device disclosed herein may be used in the method.

The actuator may comprise or consist of a magnetic shape memory alloy.

In general, the actuator or the transport device may be able to be detachably connected or combined with the membrane. This means that the fluidic element may be disposed of after one-time use (disposable article) and another fluidic element may be connected or used with the actuator or the transport device. By configuring the fluidic element as a disposable article, cross-contamination can be avoided and/or sterile operation can be ensured. The actuator and/or the transport device may therefore be reusable.

The actuator or the transport device may be connected to the membrane or the fluidic element by a snap connection, a screw connection, a clamping mechanism, a pliers mechanism, a bayonet lock and/or an adhesive connection.

The actuator or the transport device may also be firmly, i.e. non-detachably, connected to the membrane or the fluidic element.

The membrane may be attached to the basic body of the fluidic element in such a way that the actuator does not come into contact with the fluid when a fluid is transported from the outlet of the first channel to the inlet of the second channel. The membrane may act or function as a media separator.

The membrane may be deformed by the actuator (simultaneously) in at least two different portions. Between the membrane and the basic body, at least two cavities may be formed (simultaneously) by the actuator.

### BRIEF DESCRIPTION OF THE DRAWINGS

The disclosure or further embodiments and advantages of the disclosure are explained in more detail below using figures, the figures merely describing exemplary embodiments of the disclosure. Identical components in the figures are given the same reference symbols. In the figures:

FIG. 1 shows a fluidic system 1000;

FIG. 2a shows a fluidic element 100 at a first point in time;

FIG. 2b shows the fluidic element 100 at a second point in time;

FIG. 2c shows the fluidic element 100 at a third point in time;

FIG. 3 shows a transport device 200;

FIG. 4 shows a portion of a fluidic system 1000;

FIG. 5 shows a portion of a fluidic system 1000;

FIG. 6 shows a portion of a fluidic system 1000;

FIG. 7 shows a portion of a fluidic system 1000; and

FIG. 8 shows a portion of a fluidic system 1000.

### DETAILED DESCRIPTION

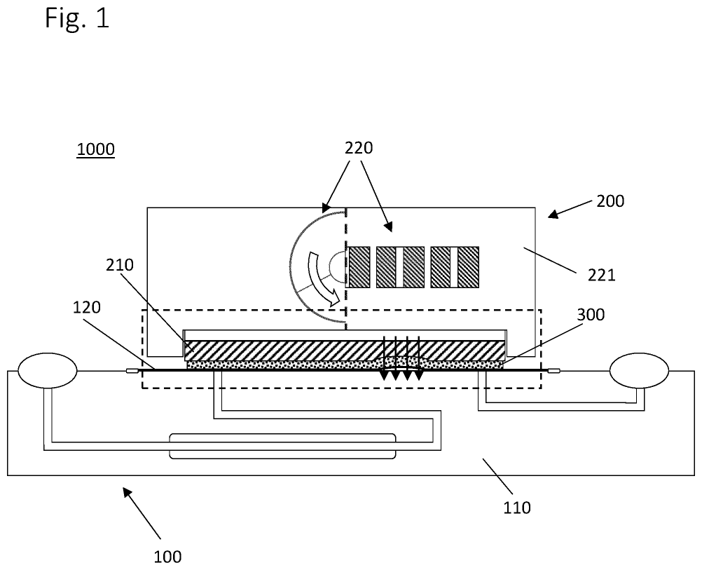

FIG. 1 shows a fluidic system 1000. The fluidic system may be a microfluidic system 1000.

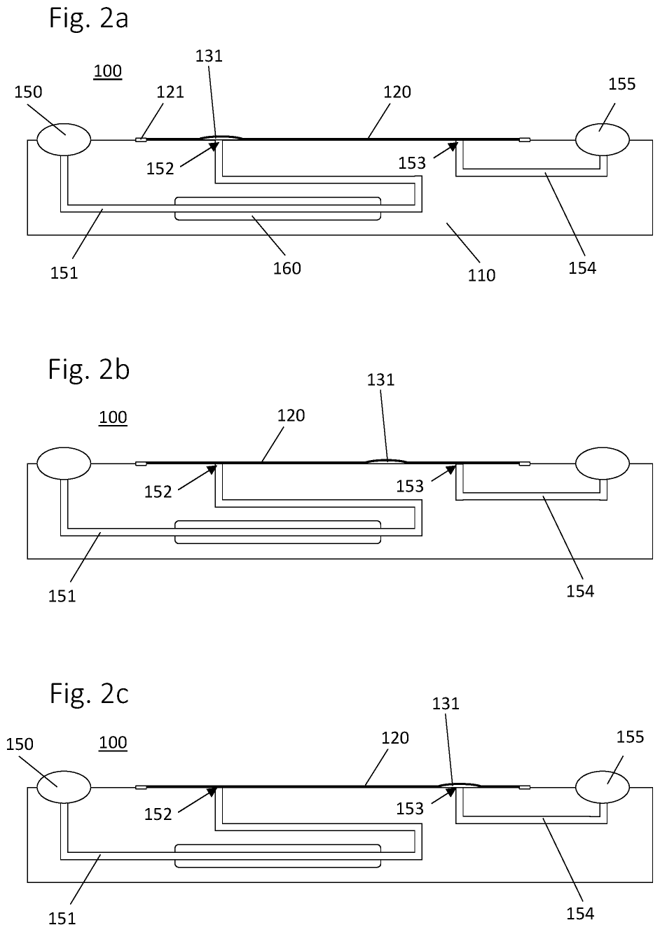

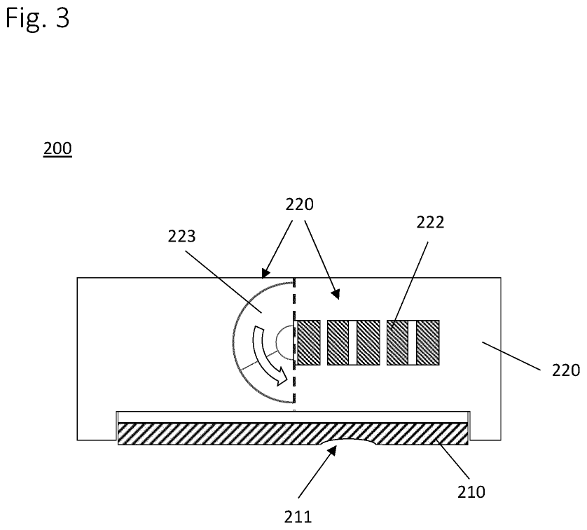

The fluidic system 1000 comprises a fluidic element 100 and a transport device 200. The fluidic element 100 and the transport device 200 are described in more detail with reference to FIGS. 2a to 2c and 3 below.

The fluidic element 100 may comprise a basic body 110. At least two channels may be formed in the basic body 100. The fluidic element 100 may comprise a membrane 120. The membrane 120 may be disposed on a surface of the basic body 110.

The transport device 200 may comprise an actuator 210. The actuator 210 may comprise or consist of a magnetic shape memory alloy. The transport device 200 may comprise a drive 220. The drive 220 may be configured to generate a homogeneously directed traveling magnetic field. The magnetic field is indicated in FIG. 1 by four parallel arrows that are directed towards the basic body 110. The drive 220 may also be configured to generate a rotating magnetic field. The actuator 210 may be deformed by the magnetic field of the drive 220. In particular, a constriction or taper may be formed in at least one surface of the actuator 210.

The fluidic element 100 may be connected to the transport device 200. In particular, the fluidic element 100 may be connected to the transport device 200 in such a way that the actuator 210 is coupled or connected to the membrane 120. The connection or coupling may take place via a contact region 300. The actuator 210 and the membrane 120 may be coupled or connected to one another in such a way that a deformation of the actuator 210 causes a (corresponding) deformation of the membrane 120. For example, when a constriction or taper is formed in the actuator 210, the membrane 120 may be deformed towards the actuator 210. In particular, the membrane 120 is deformed away from the basic body 110 or is raised or lifted off the basic body 110 when the actuator 210 is deformed.

The deformation of the membrane 120 may form a cavity 131 between the membrane 120 and the basic body 110. A fluid may be transported in the cavity 131. The transport of the fluid may be effected by the magnetic field generated by the drive travelling and the deformation of the actuator 210 travelling. When the deformation of the actuator 210 travels, the deformation of the membrane 120 may also travel, so that the cavity 131 travels.

In a region in which no deformation is formed in the actuator 210, the membrane 120 may be undeformed. In this state, the membrane 120 may rest against the basic body 110. When the membrane 120 rests against the basic body 110, there may be no fluid between the membrane 120 and the basic body 110 in this region.

The transport device 200 may comprise a housing 221. The drive 220 may be at least partially incorporated in the housing 221 of the transport device 200. The actuator 210 may be at least partially incorporated in the housing 221 of the transport device 200.

In FIGS. 2a to 2c, a fluidic element 100 is shown at three different points in time.

In FIG. 2a, the fluidic element 100 is shown at a first point in time. The fluidic element 100 may comprise a basic body 110. At least one first channel 151 and at least one second channel 154 may be formed in the basic body 110. The basic body may be an injection-molded part. The first channel 151 and the second channel 154 may have been formed in the basic body 110 as part of the injection molding process.

Fluid may be introduced into the first channel 151 via an inlet 150. An outlet 152 may be formed at one end of the first channel 151. The outlet 152 may open into a surface of the basic body 110 or be formed therein. The outlet 152 of the first channel 151 may be covered or overlapped by the membrane 120.

The fluidic element 100 may comprise at least one second channel 154. The second channel 154 may be formed in the basic body. The second channel 154 may comprise an outlet 155. A fluid may emerge or be discharged from the outlet 155 of the second channel 154. An inlet 153 may be formed at one end of the second channel 154. The inlet 153 of the second channel 154 may be formed in a surface of the basic body 110 or may open into it. The inlet 153 of the second channel 154 may be overlapped or covered by the membrane 120.

The inlet 153 of the second channel 154 may be formed in or can open into the same side of the basic body 110 as the outlet 152 of the first channel 151. In particular, the inlet 153 of the second channel 154 and the outlet 152 of the first channel 151 are formed in or open into a surface portion of the basic body 110 that is planar, flat or plane.

The membrane 120 may be fastened to the side of the basic body 110 where the inlet 153 of the second channel 154 and the outlet 152 of the first channel 151 are formed or open into.

The membrane 120 may comprise an attachment 121 (also referred to as fastening). The attachment 121 may completely surround a surface portion of the membrane 120 and/or the basic body 110. The attachment 121 may be an adhesive bond, an adhesive seam, a weld and/or a weld seam. For example, the membrane 120 is adhesively bonded or welded to the basic body 110.

The fluidic element 110 may comprise a process unit 160. A sample may be treated or analyzed in the process unit 160. For example, the process unit 160 may be arranged upstream of the outlet 152 of the first channel 151. Likewise, the processing unit 160 may be arranged downstream of the inlet 153 of the second channel 154.

A sample may flow with a fluid through the first and/or second channel 151, 154 to be treated or analyzed in the process unit 160. The sample may be subjected to a chemical, physical and/or biological process by the process unit 160.

At the first point in time (see FIG. 2a), the membrane 120 is deformed in the region of the outlet 152 of the first channel 151. The deformation of the membrane 120 is caused by the actuator 210 (not shown in FIG. 2a). Due to the deformation, a cavity 131 may form between the membrane 120 and the basic body 110. At the point in time in FIG. 2a, the cavity is in fluidic communication with the cavity 131 so that fluid can flow from the first channel 151 into the cavity 131 via the outlet 152 of the first channel 151. The formation of the cavity 131 may generate a (slight) negative pressure, making the fluid flow into the cavity 131. Likewise, fluid may flow into the inlet 150 of the first channel 151.

FIG. 2b shows the fluidic element 100 as described with regard to FIG. 2a at a second point in time. At the second point in time, the cavity 131 is filled with fluid and has been moved towards the inlet 153 of the second channel 154. The movement of the cavity 131 may be caused by a movement of the deformation in the actuator 210 (not shown in FIG. 2b). The movement of the deformation in the actuator 210 may be caused by a movement or change of the magnetic field generated by the drive 220.

At the second point in time, the outlet 152 of the first channel 151 may not be in fluidic communication with the cavity 131. At the second point in time, the inlet 153 of the second channel 154 may not be in fluidic communication with the cavity 131. The cavity 131 with the fluid may be completely enclosed or surrounded by the membrane 120 and the basic body 110. In particular, the actuator 210 may press the membrane 120 against the basic body 110 or press it towards the basic body 110 in a region outside the cavity 131.

FIG. 2c shows the fluidic element 100 as described with respect to FIG. 2a at a third point in time. At the third point in time, the cavity 131 filled with fluid has been moved into the region of the inlet 153 of the second channel 154. The movement of the cavity 131 may be caused by a movement of the deformation in the actuator 210 (not shown in FIG. 2c). The movement of the deformation in the actuator 210 may be caused by a movement or change in the magnetic field generated by the drive 220.

At the third point in time, the cavity 131 may be in fluidic communication with the inlet 153 of the second channel 154. As a result, fluid from the cavity 131 can flow into the second channel 154 via the inlet 153 of the second channel 154. Likewise, fluid can flow out of the outlet 155 of the second channel 154.

FIG. 3 shows a transport device 200. The transport device 200 may comprise an actuator 210. In particular, the actuator 210 comprises or consists of a magnetic shape memory alloy.

The transport device 200 may comprise a drive 220. The drive 220 may be configured to generate a magnetic field. The magnetic field may be a homogeneously directed traveling magnetic field. The magnetic field may form a deformation 211 in the actuator 210. The deformation 211 may be a constriction or a taper. The deformation 211 of the actuator 210 may deform the membrane 120.

The drive 220 may comprise a plurality of electromagnetic coils 222. The electromagnetic coils 222 may be arranged along the actuator 210. The electromagnetic coils 222 may be closed-loop or open-loop controlled so that a magnetic field travels along the actuator 210. The deformation 211 may travel in the actuator 210 due to the traveling magnetic field.

The drive 220 may comprise at least one magnet 223, in particular a diametrical magnet. In a diametrical magnet, the magnet axis extends through the diameter. The poles on the magnetic surfaces are opposite each other. The magnet 223 may be closed-loop or open-loop controlled such that a magnetic field travels along the actuator 210.

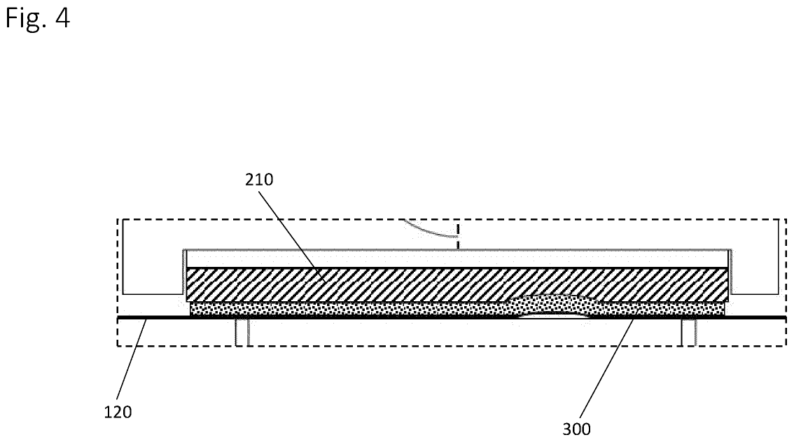

FIG. 4 shows a portion of a fluidic system 1000, as indicated in FIG. 1.

A contact region 300 may be formed between the actuator 210 and the membrane 120. The contact region 300 may be used to create or strengthen a connection between the actuator 210 and the membrane 120. For example, the contact region 300 may provide an adhesive force between the actuator 210 and the membrane. Likewise, an adhesive bond between the actuator 210 and the membrane 120 may be provided in the contact region 300.

A liquid, e.g. silicone oil, may be provided in the contact region 300 between the actuator 210 and the membrane 120. The liquid may create or strengthen an adhesive force between the actuator 210 and the membrane.

An adhesive bond may be provided in the contact region 300 between the actuator 210 and the membrane 120. The adhesive bond may be provided by an adhesive film or an adhesive membrane. The adhesive membrane may be a one-sided or two-sided adhesive membrane.

A gel may be provided in the contact region 300. Preferably, a hydrocolloid film is provided in the contact region 300.

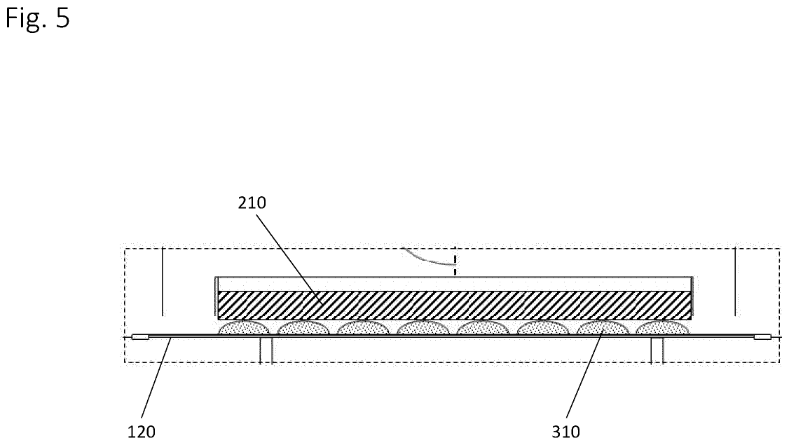

FIG. 5 shows a portion of a fluidic system 1000, as indicated in FIG. 1.

Capsules 310 may be arranged between the actuator 210 and the membrane 120. The capsules 310 may each have a shell. An adhesion medium may be contained in the shell. When the actuator 210 is pressed or pushed onto the membrane 120, the shell of the capsule may be damaged or break open. This allows for the adhesion medium to exit from the interior of the capsule and get between the actuator 210 and the membrane 120. The adhesion medium may provide an adhesive force between the actuator 210 and the membrane 120.

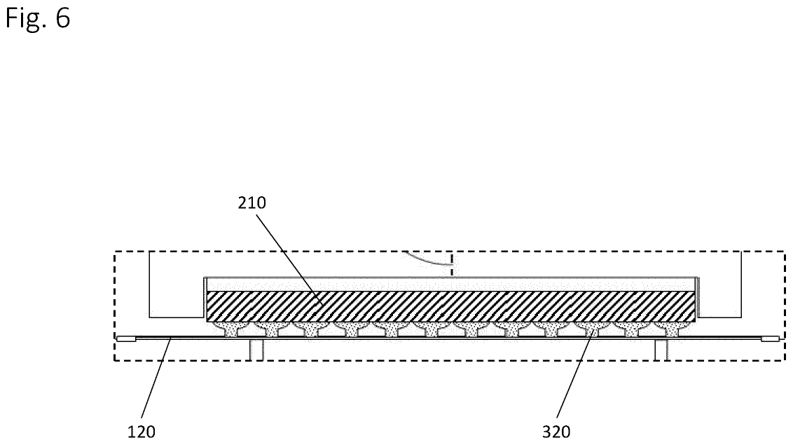

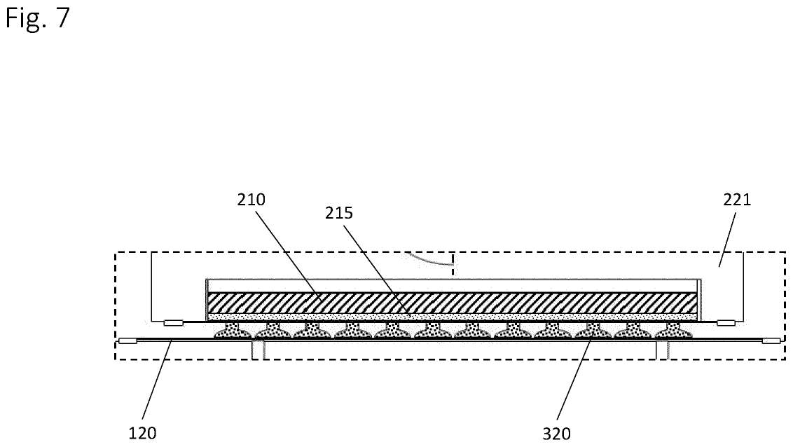

FIGS. 6 and 7 show a portion of a fluidic system 1000, as indicated in FIG. 1.

Adhesive elements 320 may be arranged between the actuator 210 and the membrane 120. The adhesive elements 320 may cause or increase van der Waals forces and/or electrostatic forces between the actuator 210 and the membrane 120. A plurality of adhesive elements 320 may be provided between the actuator and the membrane 120, for example at least 100, preferably at least 500, more preferably at least 1000 adhesive elements 320.

The adhesive elements 320 can be provided on the membrane 120. In particular, the membrane 120 can comprise the adhesive elements 320. The adhesive elements 320 may be firmly connected to the membrane 120.

The adhesive elements 320 may also be provided on the actuator 210. In particular, the actuator 210 may comprise the adhesive elements 320. The adhesive elements 320 may be firmly connected to the actuator 210.

An adhesive membrane 215 may be provided between the actuator 210 and the membrane 120 (see FIG. 7). The adhesive membrane 215 may comprise the adhesive elements 320. In particular, the adhesive elements 320 may be firmly connected to the adhesive membrane 215. The adhesive membrane 215 may be firmly or detachably connected to the transport device 200, in particular to the actuator 210 or to the housing 221 of the transport device 200. Likewise, the adhesive membrane 215 may be firmly or detachably connected to the fluidic element 100, in particular to the membrane 120 or to the basic body 110.

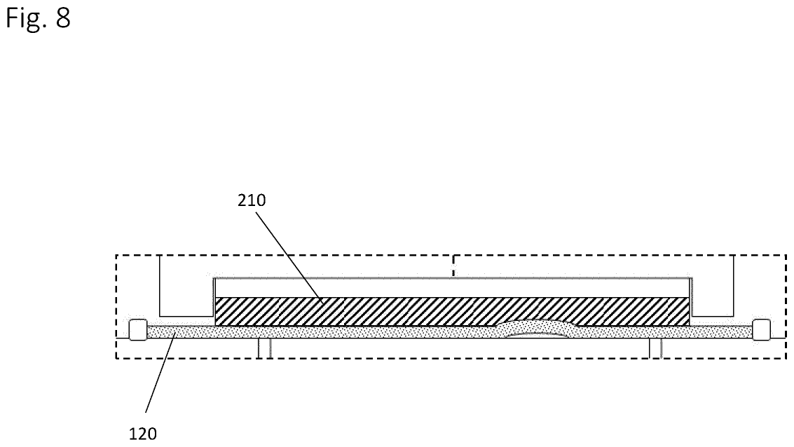

FIG. 8 shows a portion of a fluidic system 1000, as indicated in FIG. 1.

A magnetic force may act between the actuator 210 and the membrane 120. For example, the membrane may be magnetic or magnetizable. Preferably, the membrane 120 has a ferromagnetic property or is ferromagnetic. The actuator 210 may be magnetic or magnetizable.

Numbered examples of the disclosure are given below:

1. A fluidic element (100), comprising:
a basic body (110) having at least one first channel (151) and at least one second channel (154) for guiding a fluid, wherein at least one outlet (152) is formed at one end of the first channel (151) and at least one inlet (153) is formed at one end of the second channel (154); and
a deformable membrane (120) connected to the basic body (110) and covering at least the outlet (152) of the first channel (151) and the inlet (153) of the second channel (154),
wherein the membrane (120) can be deformed by an actuator (210) towards the actuator (110) such that a movable cavity (131) is formed between the basic body (110) and the membrane (120) in order to transport the fluid from the outlet (152) of the first channel (151) to the inlet (153) of the second channel (154).

2. The fluidic element according to example 1, wherein the membrane (120) is connected to a surface of the basic body (110) via an attachment (121) and the attachment (121) completely surrounds a surface portion of the membrane (120).

3. The fluidic element according to example 1 or 2, wherein a sample can be introduced into the fluidic element (100) and wherein the fluidic element (100) comprises a process unit (160), wherein the sample can be treated in the process unit (160) by a chemical, physical and/or biological process.

4. The fluidic element according to one of examples 1 to 3, wherein the membrane (120) is connected to the basic body (110) such that a portion of the membrane (120) that is not deformed by the actuator (110) contacts the basic body (110).

5. A fluidic system (1000) comprising a fluidic element (100), in particular a fluidic element (100) according to one of the preceding examples, and a transport device (200), wherein:
the fluidic element (100) comprises a basic body (110) and a deformable membrane (120), wherein the basic body (110) comprises at least one first channel (151) and at least one second channel (154) for guiding a fluid, wherein at least one outlet (152) is formed at one end of the first channel (151) and at least one inlet (153) is formed at one end of the second channel (154), wherein the membrane (120) is connected to the basic body and covers at least the outlet (152) of the first channel (151) and the inlet (153) of the second channel (154);
the transport device (200) comprises an actuator (210), wherein the actuator (210) is configured to deform the membrane (120) such that a cavity (131) is formed between the basic body (110) and the membrane (120).

6. The fluidic system (1000) according to example 5, wherein the actuator (210) comprises or consists of a magnetic shape memory alloy.

7. The fluidic system (1000) according to example 5 or 6, wherein the transport device (200) comprises a drive (220), wherein the drive (220) is configured to deform the actuator (210), in particular wherein the drive (220) is configured to generate a magnetic field.

8. The fluidic system (1000) according to one of examples 5 to 7, wherein the actuator (210) and the membrane (120) are coupled to one another such that a deformation of the actuator (210) causes a deformation of the membrane, in particular such that a deformation of the actuator (210) causes a corresponding deformation of the membrane (120).

9. The fluidic system (1000) according to one of examples 5 to 8, wherein the actuator (210) is connected to the membrane (120) by an adhesive force.

10. The fluidic system (1000) according to example 9, wherein the adhesive force is provided by a fluid, preferably a liquid, more preferably silicone oil, between the actuator (210) and the membrane (120).

11. The fluidic system (1000) according to example 9, wherein the adhesive force is provided by an adhesion medium that was provided by breaking open capsules between the actuator (210) and the membrane (120).

12. The fluidic system (1000) according to example 9, wherein the adhesive force is provided by a gel, in particular by a hydrocolloid film, between the actuator (210) and the membrane (120).

13. The fluidic system (1000) according to one of examples 5 to 8, wherein the actuator (210) is connected to the membrane (120) by an adhesive bond.

14. The fluidic system (1000) according to example 13, wherein the adhesive bond is provided by an adhesive film between the actuator (210) and the membrane (120) or wherein the adhesive bond is provided by an adhesive membrane between the actuator (210) and the membrane (120).

15. The fluidic system (1000) according to one of examples 5 to 8, wherein the actuator (210) is connected to the membrane (120) by van der Waals forces and/or electrostatic forces, in particular wherein the actuator (210) and/or the membrane (120) includes a plurality of adhesive elements (320).

16. The fluidic system (1000) according to one of examples 5 to 8, wherein the actuator (210) is connected to the membrane (120) by a negative pressure.

17. The fluidic system (1000) according to one of examples 5 to 8, wherein the actuator (210) is connected to the membrane (120) by a magnetic force, in particular wherein the membrane (120) is magnetic.

18. A method for operating a fluidic system (1000), in particular a fluidic system (1000) according to one of examples 5 to 17, the method comprising the steps of:
deforming a membrane (120) connected to a basic body (110) by an actuator (210) in the direction of the actuator (210) so that a cavity (131) is formed between the basic body (110) and the membrane (120);
introducing a fluid from an outlet (152) of a first channel (151) of the basic body (110) into the cavity (131);
moving the cavity (131) with the fluid through the actuator (210) towards an inlet (153) of a second channel (154);
introducing the fluid into the second channel (154) via the inlet (153).

19. The method according to example 18, wherein the actuator (210) comprises or consists of a magnetic shape memory alloy.

1. A fluidic system (1000) comprising a fluidic element (100) and a transport device (200), wherein:
said fluidic element (100) comprises a basic body (110) and a deformable membrane (120), wherein said basic body (110) comprises at least one first channel (151) and at least one second channel (154) for guiding a fluid, wherein at least one outlet (152) is formed at one end of said first channel (151) and at least one inlet (153) is formed at one end of said second channel (154), wherein said membrane (120) is connected to said basic body and covers at least said outlet (152) of said first channel (151) and said inlet (153) of said second channel (154), wherein the connection between the membrane (120) and the basic body (111) is firm;
said transport device (200) comprises an actuator (210), wherein said actuator (210) is configured to deform said membrane (120) such that a cavity (131) is formed between said basic body (110) and said membrane (120),
wherein said actuator (210) comprises or consists of a magnetic shape memory alloy.

2. The fluidic system (1000) according to claim 1, wherein said actuator (210) is detachably connectable to said membrane (120).

3. The fluidic system (1000) according to claim 1, wherein said transport device (200) comprises a drive (220), wherein said drive (220) is configured to deform said actuator (210), in particular wherein said drive (220) is configured to generate a magnetic field.

4. The fluidic system (1000) according to claim 1, wherein said actuator (210) and said membrane (120) are coupled to one another such that a deformation of said actuator (210) causes a deformation of said membrane, in particular that a deformation of said actuator (210) causes a corresponding deformation of said membrane (120).

5. The fluidic system (1000) according to claim 1, wherein said actuator (210) is connected to said membrane (120) by an adhesive force.

6. The fluidic system (1000) according to claim 5, wherein the adhesive force is provided by a fluid, preferably a liquid, more preferably silicone oil, between said actuator (210) and said membrane (120).

7. The fluidic system (1000) according to claim 5, wherein the adhesive force is provided by an adhesion medium that was provided by breaking open capsules between said actuator (210) and said membrane (120).

8. The fluidic system (1000) according to claim 5, wherein the adhesive force is provided by a gel, in particular by a hydrocolloid film, between said actuator (210) and said membrane (120).

9. The fluidic system (1000) according to claim 1, wherein said actuator (210) is connected to said membrane (120) by an adhesive bond.

10. The fluidic system (1000) according to claim 9, wherein the adhesive bond is provided by an adhesive film between said actuator (210) and said membrane (120) or wherein the adhesive bond is provided by an adhesive membrane between said actuator (210) and said membrane (120).

11. The fluidic system (1000) according to claim 1, wherein said actuator (210) is connected to said membrane (120) by van der Waals forces and/or electrostatic forces, in particular wherein said actuator (210) and/or said membrane (120) includes a plurality of adhesive elements (320).

12. The fluidic system (1000) according to claim 1, wherein said actuator (210) is connected to said membrane (120) by a negative pressure.

13. The fluidic system (1000) according to claim 1, wherein said actuator (210) is connected to said membrane (120) by a magnetic force, in particular wherein said membrane (120) is magnetic.

14. The fluidic system (1000) according to claim 1, wherein said membrane (120) is connected to a surface of said basic body (110) via an attachment (121) and said attachment (121) completely surrounds a surface portion of said membrane (120).

15. The fluidic system (1000) according to claim 1, wherein a sample is introducible into said fluidic element (100) and wherein said fluidic element (100) comprises a process unit (160), wherein the sample is treatable by a chemical, physical and/or biological process in said process unit (160).

16. The fluidic system (1000) according to claim 1, wherein said membrane (120) is connected to said basic body (110) in such a way that a portion of said membrane (120) that is not deformed by said actuator (110) contacts said basic body (110).

17. A method for operating a fluidic system (1000), in particular a fluidic system (1000) according to claim 1, said method comprising the steps of:
deforming a membrane (120) connected to a basic body (110) by means of an actuator (210) towards said actuator (210) such that a cavity (131) is formed between said basic body (110) and said membrane (120), wherein said actuator (210) comprises or consists of a magnetic shape memory alloy, wherein the connection between the membrane (120) and the basic body (111) is firm;
introducing a fluid from an outlet (152) of a first channel (151) of said basic body (110) into said cavity (131);
moving said cavity (131) with the fluid towards an inlet (153) of a second channel (154) by means of said actuator (210);
introducing the fluid into said second channel (154) via said inlet (153).

18. The fluidic system (1000) according to claim 1, wherein the connection between the membrane (120) and the basic body (110) is such that the membrane (120) cannot be removed from the basic body without causing damage or destruction.

19. The fluidic system (1000) according to claim 1, wherein the membrane (120) is glued or welded to the basic body (110).
